(19) United States
(12) Patent Application Publication
(10) Pub. No.: US 2025/0332960 A1
(43) Pub. Date: Oct. 30, 2025

(54) VEHICLE

(71) Applicants: Hyundai Motor Company, Seoul (KR); Kia Corporation, Seoul (KR)

(72) Inventors: Myung Hwan Kim, Hwaseong-Si (KR); Gab Bae Jeon, Hwaseong-Si (KR); Min Seong Kim, Hwaseong-Si (KR)

(21) Appl. No.: 18/828,953

(22) Filed: Sep. 9, 2024

(30) Foreign Application Priority Data
Apr. 24, 2024 (KR) 10-2024-0054894

(51) Int. Cl. B60L 58/26; B60L 53/22; H01M 10/613; H01M 10/625; H01M 10/656; H01M 10/663; H05K 7/20

(52) U.S. Cl. CPC B60L 58/26; B60L 53/22; H01M 10/613; H01M 10/625; H01M 10/656; H01M 10/663; H05K 7/20927; H01M 2220/20

(57) ABSTRACT

A vehicle may include a cooling target component part to be cooled. The vehicle may include a cooling target component part cooling line through which a first heat exchange fluid for cooling the cooling target component part flows, a vehicle air conditioning line through which a second heat exchange fluid, which heats or cools an internal space of the vehicle while exchanging heat with the internal space of the vehicle, flows, and a connection line extending from the cooling target component part line toward the vehicle air conditioning line and configured to define and/or supply a region in which the first heat exchange fluid and the second heat exchange fluid exchange heat with each other.

### CROSS-REFERENCE TO RELATED APPLICATION

This application claims priority to and the benefit of Korean Patent Application No. 10-2024-0054894 filed in the Korean Intellectual Property Office on Apr. 24, 2024, the entire contents of which are incorporated herein by reference.

### TECHNICAL FIELD

The present disclosure relates to a vehicle, and more particularly, to a vehicle equipped with a cooling apparatus capable of cooling motorization equipment in the vehicle.

### BACKGROUND

An electric vehicle, which operates wheels by using electrical energy of a battery as a power source, needs to effectively dissipate heat generated from the battery as well as heat generated from motors that operate the wheels. In many cases, a radiator is mounted in the electric vehicle to recover heat from heat generation components, including the battery and the motor, and discharge the heat to the outside. In order to meet increasing demands for aesthetic design of vehicles, studies are being actively conducted to improve the aesthetic appearances of the vehicles.

However, in the related art, in case that the radiator is mounted in the vehicle, a volume occupied by the radiator severely restricts the design of the vehicle. In particular, in case that the radiator is mounted in the vehicle, it is impossible to reduce a height of a platform of the vehicle or design a platform having an overall flat shape. Furthermore, in case that the radiator is mounted in the vehicle, a bumper hole, through which cooling air is introduced, needs to be formed in the vicinity of the radiator. However, the bumper hole also degrades not only the aesthetic appearance of the vehicle but also overall aerodynamic performance of the vehicle.

### SUMMARY

The following summary presents a simplified summary of certain features. The summary is not an extensive overview and is not intended to identify key or critical elements.

Systems, apparatuses, and methods are described for a cooling apparatus for a cooling motorization equipment in a vehicle. A vehicle may comprise a cooling target component; a cooling line configured to allow a first heat exchange fluid to flow for cooling the cooling target component; a vehicle air conditioning line configured to allow a second heat exchange fluid to flow and exchange heat with an internal space of the vehicle; and a connection line extending from the cooling line toward the vehicle air conditioning line and comprising a region configured to allow for the first heat exchange fluid and the second heat exchange fluid to exchange heat with each other.

These and other features and advantages are described in greater detail below.

### BRIEF DESCRIPTION OF THE DRAWINGS

FIG. 1 is a cross-sectional side view schematically illustrating a cross-sectional structure of a vehicle according to the present disclosure.

FIG. 2 is a view schematically illustrating a cooling target component part cooling line, a vehicle air conditioning line, a connection line, and components provided in/connected to the lines provided in the vehicle according to the present disclosure.

FIG. 3 is a side view illustrating a cooling target component part and the cooling target component part cooling line provided in the vehicle according to the present disclosure.

FIG. 4 is a perspective view illustrating an air conditioner part and a vehicle air conditioning line provided in the vehicle according to the present disclosure.

### DETAILED DESCRIPTION

Hereinafter, a vehicle will be described with reference to the drawings.

### Vehicle

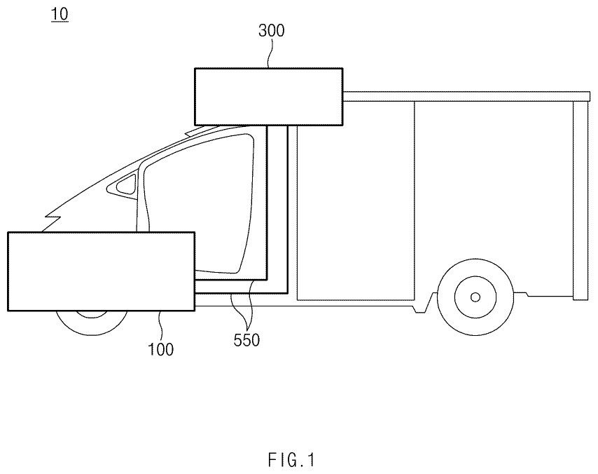

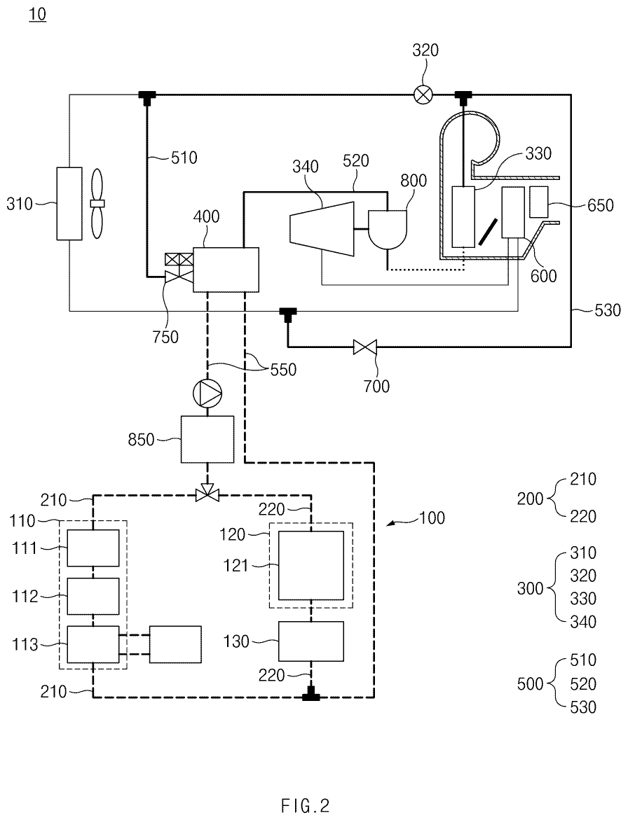

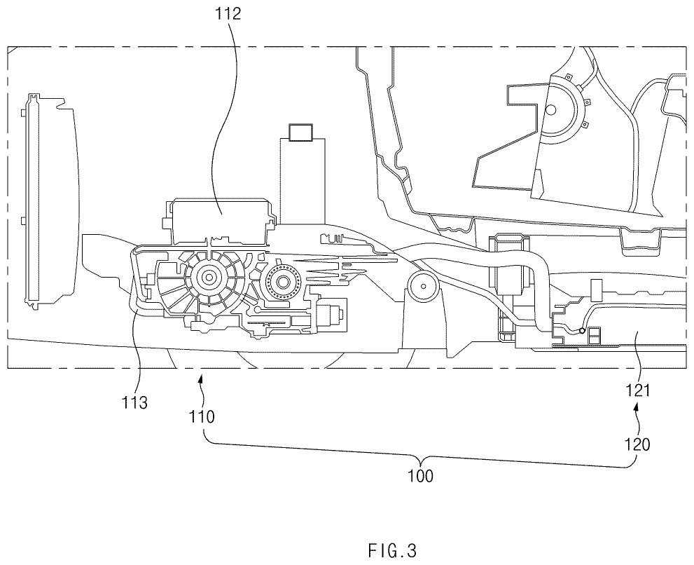

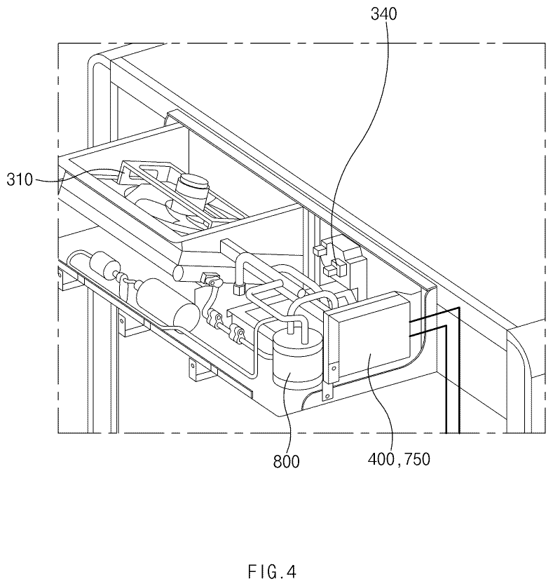

FIG. 1 is a cross-sectional side view schematically illustrating a cross-sectional structure of a vehicle according to the present disclosure, and FIG. 2 is a view schematically illustrating a cooling target component part cooling line, a vehicle air conditioning line, a connection line, and components provided in the lines provided in the vehicle according to the present disclosure. FIG. 3 is a side view illustrating a cooling target component part and the cooling target component part cooling line provided in the vehicle according to the present disclosure, and FIG. 4 is a perspective view illustrating an air conditioner part and a vehicle air conditioning line provided in the vehicle according to the present disclosure.

According to the present disclosure, an air conditioner for a vehicle (e.g., which is mounted in the vehicle) may be used to cool a cooling fluid (e.g., a coolant) that cools cooling target components required to be cooled in the vehicle. Therefore, according to the present disclosure, it is possible to cool the cooling fluid without a separate radiator for cooling the cooling fluid that cools the cooling target components. Therefore, according to the present disclosure, the radiator may be excluded from the vehicle, which may reduce an overall volume of the vehicle and/or improve utilization of an internal space of the vehicle. Also, or alternatively, according to the present disclosure, it is possible to reduce a height of a platform of the vehicle in comparison with a height of a platform of a vehicle in which a radiator in the related art is mounted. Also, or alternatively, it is possible to also improve a degree of design freedom of the vehicle that has been restricted by the radiator.

With reference to the drawings, a vehicle 10 may include a cooling target component part 100 (a cooling target, a cooling target component, a cooling target device, a cooling target circuit, etc.) to be cooled, and a cooling target component part cooling line 200 (a cooling line) through which a first heat exchange fluid for cooling the cooling target component part 100 may flow. The first heat exchange fluid may be a coolant. The vehicle 10 may be an electric vehicle configured to use electrical energy to operate wheels or other vehicular functions. The electrical energy may be stored in a battery as a power source. The cooling target component part 100 may include at least one of an integrated charging control unit (ICCU) 111, an inverter 112, an oil cooler 113, and/or a battery 121. For example, the oil cooler 113 may be configured to cool oil for cooling a motor mounted in the vehicle.

Also, or alternatively, the vehicle 10 may include a vehicle air conditioning line 500 through which a second heat exchange fluid, which heats or cools an internal space of the vehicle by exchanging heat with the internal space of vehicle, flows, and an air conditioner part 300 (e.g., air conditioner) provided in/in communication with/connected to the vehicle air conditioning line 500. The air conditioner part 300 may be configured to lower a temperature of the internal space of the vehicle by absorbing thermal energy from the internal space of the vehicle. However, as described herein, the vehicle air conditioning line 500 may further include a configuration for raising a temperature of the internal space of the vehicle in addition to the air conditioner part 300 for lowering a temperature of the internal space of the vehicle. For example, the second heat exchange fluid may be a refrigerant generally used for an air conditioner for a vehicle.

According to the present disclosure, it is possible to cool the cooling fluid without a separate radiator for cooling the cooling fluid that cools the cooling target components. In order to achieve the above-mentioned object, the vehicle 10 may further include a connection line 550 extending from the cooling target component part cooling line 200 toward the vehicle air conditioning line 500 and configured to define and/or supply a region in which the first heat exchange fluid and the second heat exchange fluid exchange heat with each other. More specifically, the first heat exchange fluid may be supplied, via the connection line 550, to the cooling target component part cooling line 200 and the first heat exchange fluid and the second heat exchange fluid may exchange heat with each other in one region of the connection line 550 (e.g., such that the first heat exchange fluid may be cooled, and the second heat exchange fluid may be heated).

As illustrated in FIGS. 1, 3, and 4, the vehicle air conditioning line 500 and the air conditioner part 300 may be provided in a first (e.g., an upper) region of the vehicle, and the cooling target component part cooling line 200 and the cooling target component part 100 may be provided in a second (e.g., a front and/or lower) region of the vehicle. Therefore, the connection line 550 may include a region that penetrates the vehicle 10 in one or more directions (e.g., a forward/rearward direction and an upward/downward) so that the first heat exchange fluid may move from the cooling target component part cooling line 200 toward the vehicle air conditioning line 500.

For example, as illustrated in FIG. 1, the connection line 550 may be provided to sequentially pass through a driver seat rear region of the vehicle 10 and a driver seat lower region of the vehicle. For example, the connection line 550 may be fixed to a B-pillar of the vehicle 10 and/or a floor member of the vehicle.

With continued reference to the drawings, the vehicle 10 may further include the air conditioner part 300 provided in/in communication with/connected to the vehicle air conditioning line 500. As described herein, the air conditioner part 300 may be configured to lower a temperature of the internal space of the vehicle.

The air conditioner part 300 may include a condenser 310, which may be provided in/in communication with/connected to the vehicle air conditioning line 500 and/or configured to discharge heat from the second heat exchange fluid to the outside, and a main expansion valve 320 connected to the condenser 310 through the vehicle air conditioning line 500 and configured to receive the first heat exchange fluid discharged from the condenser 310. As the second heat exchange fluid throttled in the main expansion valve 320, such that a pressure of the second heat exchange fluid may be rapidly decreased, and a temperature of the second heat exchange fluid may also be decreased. For example, the main expansion valve 320 may be a thermal expansion valve.

Also, or alternatively, the air conditioner part 300 may further include an evaporator 330 (e.g., provided in/in communication with/connected to the vehicle air conditioning line 500), connected to the main expansion valve 320 through the vehicle air conditioning line 500, and configured to receive the second heat exchange fluid discharged from the main expansion valve 320. The air conditioner part may include a compressor 340 provided in/in communication with/connected to the vehicle air conditioning line 500, connected to the evaporator 330 through the vehicle air conditioning line 500, and configured to receive the second heat exchange fluid discharged from the evaporator 330.

The first heat exchange fluid, which may be supplied to the vehicle air conditioning line 500 through the connection line 550, may exchange heat with the second heat exchange fluid in the configuration disposed in the vehicle air conditioning line 500.

As illustrated in FIG. 2, the vehicle 10 may further include a chiller part 400 (e.g., chiller and/or heat exchanger) provided in/in communication with/connected to the vehicle air conditioning line 500 and configured to receive the second heat exchange fluid from the air conditioner part 300 through the vehicle air conditioning line 500 and then discharge the second heat exchange fluid to the air conditioner part 300 through the vehicle air conditioning line 500. The connection line 550 may be provided to pass through the chiller part 400 (e.g., the region of the connection line 550 may pass through the chiller part 400), such that the first heat exchange fluid and the second heat exchange fluid may exchange heat with each other in the chiller part 400.

Referring to FIG. 2, the first heat exchange fluid may be introduced into the chiller part 400 through the connection line 550, and the second heat exchange fluid may be introduced into the chiller part 400 through the vehicle air conditioning line 500. Thereafter, the first heat exchange fluid and the second heat exchange fluid may exchange heat with each other in the chiller part 400, and the first heat exchange fluid having a relatively high temperature may transfer thermal energy to the second heat exchange fluid having a relatively low temperature, such that the first heat exchange fluid may be cooled and then discharged from the chiller part 400. The chiller part 400 may be a kind of heat exchanger, and various types of heat exchangers may be applied as the chiller part 400. For example, the chiller part 400 may be a plate-shaped heat exchanger.

The vehicle air conditioning line 500 may include i) a line that provides a route along which the second heat exchange fluid flows in case that the air conditioner part 300 operates to lower a temperature of the internal space of the vehicle by using the air conditioner part 300, and ii) a line branching off from the i) line to supply the second heat exchange fluid to the chiller part 400.

As illustrated in FIG. 2, the vehicle air conditioning line 500 may include a first branch line 510, as the line branching off from the i) line, branching off from a portion of the vehicle air conditioning line 500, which connects the condenser 310 and the main expansion valve 320, and connected to the chiller part 400.

In case that the air conditioner part 300 operates, the second heat exchange fluid may sequentially flow via the air conditioning line 500 through the condenser 310, the main expansion valve 320, the evaporator 330, and the compressor 340 to perform the general function of the air conditioner part (e.g., cooling and/or dehumidifying the internal space of the vehicle). The second heat exchange fluid in the condenser 310 may discharge thermal energy (e.g., to the outside), so the second heat exchange fluid discharged from the condenser 310 may be in a relatively low-temperature state. That is, the second heat exchange fluid discharged from the condenser 310 may have a temperature condition suitable for cooling the first heat exchange fluid. Therefore, according to the present disclosure, the first branch line 510 may branch off from the portion of the vehicle air conditioning line 500 that connects the condenser 310 and the main expansion valve 320.

The vehicle 10 may include a branch expansion valve 750 (e.g., provided in/in communication with/connected to the first branch line 510). That is, the second heat exchange fluid, which flows through the first branch line 510, may pass through the branch expansion valve 750 before being supplied to the chiller part 400. The pressure and temperature of the second heat exchange fluid may decrease while the second heat exchange fluid passes through the branch expansion valve 750.

Also, or alternatively, with continued reference to FIG. 2, the vehicle air conditioning line 500 may further include a second branch line 520 configured to connect the chiller part 400 and the compressor 340. Therefore, the second heat exchange fluid, which is introduced into the chiller part 400 through the first branch line 510, may exchange heat with the first heat exchange fluid in the chiller part 400 and then be supplied to the compressor 340 through the second branch line 520. As illustrated in FIG. 2, an accumulator 800 may be provided in/in communication with/connected to the second branch line 520. The accumulator 800 may be configured to protect the compressor 340 by separating a liquid from the second heat exchange fluid introduced toward the compressor 340.

The cooling target component part 100, which is configured to be cooled by the first heat exchange fluid, may include a first cooling target component part 110 and a second cooling target component part 120 provided separately from the first cooling target component part 110. In this case, according to the present disclosure, the cooling target component part cooling line 200 may include a first cooling target line 210 through which the first heat exchange fluid flows to cool the first cooling target component part 110, and a second cooling target line 220 through which the first heat exchange fluid flows to cool the second cooling target component part 120.

More specifically, the cooling target component part cooling line 200 may include the first cooling target line 210 through which the first heat exchange fluid discharged from the chiller part 400 is supplied to the first cooling target component part 110, and the second cooling target line 220 through which the first heat exchange fluid discharged from the chiller part 400 is supplied to the second cooling target component part 120.

In this case, as illustrated in FIG. 2, the first cooling target line 210 and the second cooling target line 220 may be disposed in parallel with each other. The configuration in which the two lines are disposed in parallel may mean that the first heat exchange fluid, which is discharged from the chiller part 400 and reaches the cooling target component part cooling line 200, is supplied selectively to the first cooling target line 210 or the second cooling target line 220.

The first cooling target component part 110 may be one of the ICCU 111, the inverter 112, and the oil cooler 113, and the second cooling target component part 120 may include the battery 121. Because the battery 121 generates a relatively large amount of heat, the battery 121 needs to be cooled to a relatively large extent. Therefore, the first heat exchange fluid supplied to the second cooling target line 220 needs to be used to concentratedly cool the battery 121. Therefore, the battery 121 may be cooled in a line provided separately from the lines in which other components in the cooling target component part 100 are provided. A temperature-raising heater 130 may be additionally provided in/in communication with/connected to the second cooling target line 220. The temperature-raising heater 130 may be provided in/in communication with/connected to an upstream region of the battery 121 based on a flow direction of the second heat exchange fluid. The temperature-raising heater 130 may be configured to heat the battery 121 to meet a temperature condition required to initially operate the battery 121.

The vehicle 10 may further include not only a configuration for lowering a temperature of the internal space of the vehicle but also a configuration for raising a temperature of the internal space of the vehicle.

More specifically, with reference to FIG. 2, the vehicle air conditioning line 500 may further include a bypass line 530 extending from the main expansion valve 320 and bypasses the evaporator 330 and/or a line that connects the main expansion valve 320 and the evaporator 330. The bypass line 530 may also be a part of the vehicle air conditioning line 500 and be configured to provide a route along which the second heat exchange fluid flows. However, the bypass line 530 may provide the route along which the second heat exchange fluid flows at the time of raising a temperature of the internal space of the vehicle.

Also, or alternatively, the vehicle 10 may further include a heat pump condenser 600 connected to the compressor 340 through the vehicle air conditioning line 500 and configured to receive the second heat exchange fluid discharged from the compressor 340. The heat pump condenser 600 may be configured to supply thermal energy to the internal space of the vehicle in order to raise a temperature of the internal space of the vehicle. For example, the heat pump condenser 600, together with the evaporator 330, may be provided in one housing.

The bypass line 530 may be connected to an upstream region of the condenser 310 based on the flow direction of the second heat exchange fluid in the vehicle air conditioning line 500. More specifically, the bypass line 530 may be connected to a downstream region of the heat pump condenser 600 based on the flow direction of the second heat exchange fluid in the vehicle air conditioning line 500. That is, according to the present disclosure, the bypass line 530 may extend from the main expansion valve 320 and then be connected to a region of the vehicle air conditioning line 500 that is disposed between the condenser 310 and the heat pump condenser 600 based on the flow direction of the second heat exchange fluid.

With continued reference to FIG. 2, the vehicle may further include a bypass line expansion valve 700 provided in/in communication with/connected to the bypass line 530. The pressure and temperature of the second heat exchange fluid may decrease while the second heat exchange fluid passes through the bypass line expansion valve 700.

The vehicle 10 may further include an additional configuration for raising a temperature of the internal space of the vehicle. For example, as illustrated in FIG. 2, the vehicle 10 may further include a PTC heater 650. For example, the PTC heater 650 may be disposed adjacent to the heat pump condenser 600. The description of the operational principle of the PTC heater 650 may be replaced with the contents disclosed in the related art.

Also, or alternatively, the vehicle 10 may further include a reservoir 850 provided in/in communication with/connected to the cooling target component part cooling line 200 and/or the connection line 550 and configured to store the first heat exchange fluid discharged from the first cooling target line 210 and the second cooling target line 220.

Hereinafter, a method of operating the vehicle described herein will be described with reference to the drawings.

### Process of Cooling Interior of Vehicle

To cool the internal space of the vehicle, the second heat exchange fluid may sequentially flow, via the vehicle air conditioning line 500, through the condenser 310, the main expansion valve 320, the evaporator 330, and the compressor 340 of the air conditioner part 300. The temperature of the second heat exchange fluid in the condenser 310 may decrease by discharging heat (e.g., to the outside of the condenser 310). The pressure and temperature of the second heat exchange fluid discharged from the condenser 310 may decrease while the second heat exchange fluid passes through the main expansion valve 320. Also, or alternatively, the temperature of the second heat exchange fluid discharged from the main expansion valve 320 may increase as the second heat exchange fluid receives thermal energy from the internal space of the vehicle while passing through the evaporator 330. The pressure and temperature of the second heat exchange fluid discharged from the evaporator 330 may increase while the second heat exchange fluid passes through the compressor 340. The processes described herein may be repeated as the second heat exchange fluid discharged from the compressor 340 is supplied back to the condenser 310.

### Process of Cooling Internal Component of Vehicle

In order to cool the cooling target component part 100, the second heat exchange fluid may be discharged from the condenser 310 of the air conditioner part 300 and then pass, via the first branch line 510, through the branch expansion valve 750, such that the pressure and temperature of the second heat exchange fluid may decrease. Thereafter, the first heat exchange fluid and the second heat exchange fluid may exchange heat with each other in the chiller part 400, such that the temperature of the first heat exchange fluid decreases, and the temperature of the second heat exchange fluid increases. The first heat exchange fluid discharged from the chiller part 400 may cool the first cooling target component part 110 or the second cooling target component part 120 while flowing through the first cooling target line 210 or the second cooling target line 220. The second heat exchange fluid discharged from the chiller part 400 may be supplied to the compressor 340 through the second branch line 520 and compressed.

The process of cooling the interior of the vehicle and the process of cooling the internal component of the vehicle may be performed together. That is, a part of the second heat exchange fluid discharged from the condenser 310 may be introduced into the main expansion valve 320 and supplied to the evaporator 330, and another part of the second heat exchange fluid discharged from the condenser 310 may be introduced into the branch expansion valve 750 and supplied to the chiller part 400.

### Process of Raising Temperature of Interior of Vehicle

In order to raise a temperature of the internal space of the vehicle, the second heat exchange fluid may sequentially flow, via the air conditioning line 500 including the bypass line 530, through the evaporator 330, the compressor 340, the heat pump condenser 600, and the bypass line expansion valve 700. The temperature of the second heat exchange fluid in the evaporator 330 may increase as the second heat exchange fluid receives thermal energy, and the pressure and temperature of the second heat exchange fluid discharged from the evaporator 330 may increase as the second heat exchange fluid may be compressed in the compressor 340. The second heat exchange fluid discharged from the compressor 340 may be supplied to the heat pump condenser 600. The temperature of the second heat exchange fluid in the heat pump condenser 600 may decrease as the second heat exchange fluid supplies thermal energy to the internal space of the vehicle, and the pressure and temperature of the second heat exchange fluid discharged from the heat pump condenser 600 may decrease as the second heat exchange fluid passes through the bypass line expansion valve 700 through the bypass line 530. The processes described herein may be repeated as the second heat exchange fluid discharged from the bypass line expansion valve 700 may be supplied back to the evaporator 330.

Alternatively, in order to raise a temperature of the internal space of the vehicle, the second heat exchange fluid may sequentially flow through the compressor 340, the heat pump condenser 600, the condenser 310, the branch expansion valve 750, and the chiller part 400 through the vehicle air conditioning line 500. More specifically, the temperature and pressure of the second heat exchange fluid in the compressor 340 increase as the second heat exchange fluid may be compressed, and the temperature of the second heat exchange fluid discharged from the compressor 340 decreases in the heat pump condenser 600 as the second heat exchange fluid supplies thermal energy to the internal space of the vehicle. The second heat exchange fluid discharged from the heat pump condenser 600 may additionally discharge a part of the thermal energy from the condenser 310 to the outside of the vehicle, and the pressure and temperature of the second heat exchange fluid discharged from the condenser 310 may decrease as the second heat exchange fluid passes through the branch expansion valve 750. The second heat exchange fluid having passed through the branch expansion valve 750 may be supplied to the chiller part 400 and then exchange heat with the first heat exchange fluid, such that the temperature of the second heat exchange fluid may increase. The processes described herein may be repeated as the second heat exchange fluid discharged from the chiller part 400 may be supplied back to the compressor 340.

The vehicle 10 may be any vehicle, including new types of movable bodies, such as purpose-built vehicles (PBVs). According to the present disclosure, it may be possible to effectively dissipate heat generated from the cooling target component part without a radiator in the related art, which may contribute to reducing heights of platforms of the movable bodies including the PBVs.

An object achieved by the present disclosure is to provide a novel cooling system capable of cooling components without a component cooling radiator mounted in a vehicle in the related art.

One aspect of the present disclosure provides a vehicle, which includes a cooling target component part required to be cooled, the vehicle including: a cooling target component part cooling line through which a first heat exchange fluid for cooling the cooling target component part flows; a vehicle air conditioning line through which a second heat exchange fluid, which heats or cools an internal space of the vehicle while exchanging heat with the internal space of the vehicle, flows; and a connection line extending from the cooling target component part line toward the vehicle air conditioning line and configured to define a region in which the first heat exchange fluid and the second heat exchange fluid exchange heat with each other.

The vehicle air conditioning line may be provided in an upper region of the vehicle.

The cooling target component part cooling line may be provided in a front lower region of the vehicle.

The vehicle may include: an air conditioner part provided in the vehicle air conditioning line; and a chiller part provided in the vehicle air conditioning line and configured to receive the second heat exchange fluid from the air conditioner part through the vehicle air conditioning line and then discharge the second heat exchange fluid to the air conditioner part through the vehicle air conditioning line, in which the connection line is provided to pass through the chiller part, such that the first heat exchange fluid and the second heat exchange fluid exchange heat with each other in the chiller part.

The air conditioner part may include: a condenser provided in the vehicle air conditioning line and configured to discharge heat from the second heat exchange fluid to the outside; and a main expansion valve connected to the condenser through the vehicle air conditioning line and configured to receive the first heat exchange fluid discharged from the condenser, and the vehicle air conditioning line may include a first branch line branching off from a portion of the vehicle air conditioning line, which connects the condenser and the main expansion valve, and connected to the chiller part.

The air conditioner part may further include: an evaporator provided in the vehicle air conditioning line, connected to the main expansion valve through the vehicle air conditioning line, and configured to receive the second heat exchange fluid discharged from the main expansion valve; and a compressor provided in the vehicle air conditioning line, connected to the evaporator through the vehicle air conditioning line, and configured to receive the second heat exchange fluid discharged from the evaporator, and the vehicle air conditioning line may further include a second branch line configured to connect the chiller part and the compressor.

The vehicle air conditioning line may further include a bypass line extending from the main expansion valve and provided separately from (e.g., branching from so as to bypass) a line that connects the main expansion valve and the evaporator, and the bypass line may be connected to an upstream region of the condenser based on a flow direction of the second heat exchange fluid in the vehicle air conditioning line.

The vehicle may further include: a heat pump condenser connected to the compressor through the vehicle air conditioning line and configured to receive the second heat exchange fluid discharged from the compressor, in which the bypass line is connected to a downstream region of the heat pump condenser based on the flow direction of the second heat exchange fluid in the vehicle air conditioning line.

The vehicle may further include: a bypass line expansion valve provided in the bypass line.

The vehicle may further include: a branch expansion valve provided in the first branch line.

The cooling target component part may include: a first cooling target component part; and a second cooling target component part provided separately from the first cooling target component part, and the cooling target component part cooling line may include: a first cooling target line through which the first heat exchange fluid discharged from the chiller part is supplied to the first cooling target component part; and a second cooling target line through which the first heat exchange fluid discharged from the chiller part is supplied to the second cooling target component part.

The first cooling target line and the second cooling target line may be disposed in parallel with each other.

The first cooling target component part may include at least one of an ICCU, an inverter, and an oil cooler.

The second cooling target component part may include a battery.

The connection line may be provided to pass through a driver seat rear region of the vehicle and a driver seat lower region of the vehicle.

According to the present disclosure, it is possible to provide the novel cooling system capable of cooling the components without a component cooling radiator mounted in a vehicle in the related art.

The present disclosure has been described with reference to specific examples and the drawings, but the present disclosure is not limited thereto. The present disclosure may be carried out in various forms, by those skilled in the art to which the present disclosure pertains, within the technical spirit of the present disclosure and the scope equivalent to the appended claims.

What is claimed is:

1. A vehicle comprising:
a cooling target component;
a cooling line configured to allow a first heat exchange fluid to flow for cooling the cooling target component;
a vehicle air conditioning line configured to allow a second heat exchange fluid to flow and exchange heat with an internal space of the vehicle; and
a connection line extending from the cooling line toward the vehicle air conditioning line and comprising a region configured to allow for the first heat exchange fluid and the second heat exchange fluid to exchange heat with each other.

2. The vehicle of claim 1, wherein the vehicle air conditioning line is provided in an upper region of the vehicle.

3. The vehicle of claim 1, wherein the cooling line is provided in a front lower region of the vehicle.

4. The vehicle of claim 1, comprising:
an air conditioner connected to the vehicle air conditioning line; and
a heat exchanger connected to the vehicle air conditioning line and configured to:
receive, from the air conditioner via the vehicle air conditioning line, the second heat exchange fluid; and
discharge, via the vehicle air conditioning line, the second heat exchange fluid to the air conditioner,
wherein the region of the connection line is configured relative to the heat exchanger such that the first heat exchange fluid and the second heat exchange fluid are able to exchange heat with each other via the heat exchanger.

5. The vehicle of claim 4, wherein the air conditioner comprises:
a condenser connected to the vehicle air conditioning line and configured to discharge heat from the second heat exchange fluid; and
a main expansion valve connected, via the vehicle air conditioning line, to the condenser and configured to receive, from the condenser, the second heat exchange fluid discharged, and
wherein the vehicle air conditioning line comprises a first branch line that branches off from a first portion of the vehicle air conditioning line that connects the condenser and the main expansion valve, wherein the first branch line is connected to the heat exchanger.

6. The vehicle of claim 5, wherein the air conditioner further comprises:
an evaporator connected, via the vehicle air conditioning line, to the main expansion valve and configured to receive the second heat exchange fluid discharged from the main expansion valve; and
a compressor connected, via the vehicle air conditioning line, to the evaporator and configured to receive the second heat exchange fluid discharged from the evaporator,
wherein the vehicle air conditioning line further comprises a second branch line configured to connect the heat exchanger to the compressor.

7. The vehicle of claim 6, wherein the vehicle air conditioning line further comprises a bypass line configured to connect, by bypassing the evaporator, the main expansion valve to a second portion of the vehicle air conditioning line upstream, based on a flow direction of the second heat exchange fluid, of the condenser.

8. The vehicle of claim 7, further comprising:
a heat pump condenser connected, via the vehicle air conditioning line, to the compressor and configured to receive the second heat exchange fluid discharged from the compressor, wherein the second portion of the vehicle air conditioning line is downstream of the heat pump condenser.

9. The vehicle of claim 7, further comprising:
a bypass line expansion valve connected to the bypass line.

10. The vehicle of claim 5, further comprising:
a branch expansion valve connected to the first branch line.

11. The vehicle of claim 4, wherein the cooling target component comprises:
a first cooling target component part; and
a second cooling target component part provided separately from the first cooling target component part,
wherein the cooling line comprises:
a first cooling target line configured to allow the first heat exchange fluid to be discharged from the heat exchanger to the first cooling target component part; and
a second cooling target line configured to allow the first heat exchange fluid discharged from the heat exchanger to the second cooling target component part.

12. The vehicle of claim 11, wherein the first cooling target line and the second cooling target line are disposed in parallel with each other.

13. The vehicle of claim 11, wherein the first cooling target component part comprises at least one of an integrated charging control unit, an inverter, or an oil cooler.

14. The vehicle of claim 13, wherein the second cooling target component part comprises a battery.

15. The vehicle of claim 1, wherein the connection line passes through a rear region of a driver's seat of the vehicle and through lower region of the driver's seat of the vehicle.
